(19) United States
(12) Patent Application Publication
(10) Pub. No.: US 2009/0152684 A1
(43) Pub. Date: Jun. 18, 2009

(54) MANUFACTURE-FRIENDLY BUFFER LAYER FOR FERROELECTRIC MEDIA

(76) Inventors: Li-Peng Wang, San Jose, CA (US); Qing Ma, San Jose, CA (US); Valluri Rao, Saratoga, CA (US)

Correspondence Address: INTEL CORPORATION;c/o CPA Global, P.O. BOX 52050, MINNEAPOLIS, MN, 55402, US

(21) Appl. No.: 11/958,773

(22) Filed: Dec. 18, 2007

(51) Int. Cl. H01L 29/04; H01L 21/02

(52) U.S. Cl. 257/627; 438/3; 257/E21.04; 257/E29.004

(57) ABSTRACT

The present invention describes a method including: providing a substrate; forming a buffer layer epitaxially over the substrate with a manufacture-friendly process; forming a bottom electrode epitaxially over the buffer layer; and forming a ferroelectric layer epitaxially over the bottom electrode.

### BACKGROUND OF THE INVENTION

1. Field of the Invention

The present invention relates to a field of semiconductor integrated circuit manufacturing, and more specifically, to a method of forming a buffer layer for storage media.

2. Discussion of Related Art

A non-volatile memory (NVM) is a device that stores data and retains the data even when power has been interrupted. Most types of NVM involve accumulating charge, such as in a floating gate or a capacitor. Writing or reading the charge may involve one or more transistors.

A new type of NVM involves a seek-and-scan approach analogous to a hard drive. The seek-and-scan approach does not rely on charge storage and thus is more scalable to a larger capacity.

However, the storage media associated with the seek-and-scan approach may be very costly to produce.

### BRIEF DESCRIPTION OF THE DRAWINGS

FIG. 1 is an illustration of an elevation view of storage media including a manufacture-friendly buffer layer according to an embodiment of the present invention.

### MANUFACTURE-FRIENDLY BUFFER LAYER FOR FERROELECTRIC MEDIA

### DETAILED DESCRIPTION OF THE PRESENT INVENTION

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention.

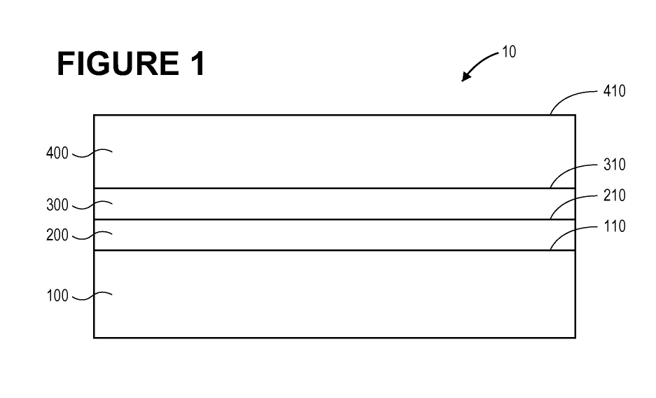

As shown in FIG. 1, an embodiment of the present invention discloses a manufacture-friendly buffer layer 200. Another embodiment of the present invention discloses storage media, such as ferroelectric media, 10 that include the manufacture-friendly buffer layer 200. Another embodiment of the present invention discloses a seek-and-scan probe (SSP) that includes the storage media 10, that include the manufacture-friendly buffer layer 200.

Also shown in FIG. 1, an embodiment of the present invention discloses a method of forming the manufacture-friendly buffer layer 200 over a substrate 100. Another embodiment of the present invention discloses a method of forming storage media, such as ferroelectric media, 10 that include the manufacture-friendly buffer layer 200. Another embodiment of the present invention discloses a method of forming a seek-and-scan probe (SSP) that includes the storage media, such as ferroelectric media, 10 that include the manufacture-friendly buffer layer 200.

In an embodiment of the present invention, the substrate 100 provides physical support for the storage media 10. In an embodiment of the present invention, the substrate 100 provides mechanical rigidity for the storage media 10. In an embodiment of the present invention, the substrate 100 provides electrical isolation for the storage media 10. In an embodiment of the present invention, the substrate 100 provides electromagnetic interference (EMI) protection for the storage media 10.

In an embodiment of the present invention, the substrate 100 includes a uniform chemical composition. In an embodiment of the present invention, the substrate 100 includes a uniform physical structure.

In order to allow integration with integrated circuit (IC) technology, the substrate 100 includes a semiconductor.

In an embodiment of the present invention, the substrate 100 includes an elemental semiconductor such as silicon, germanium, or diamond (form of carbon). In an embodiment of the present invention, the elemental semiconductor is doped. In an embodiment of the present invention, the elemental semiconductor is counter-doped.

In an embodiment of the present invention, the substrate 100 includes a compound semiconductor, including, but not limited to, silicon carbide (SiC), silicon germanium (SiGe), aluminum nitride (AlN), aluminum phosphide (AlP), gallium nitride (GaN), gallium arsenide (GaAs), indium phosphide (InP), zinc selenide (ZnSe), or cadmium telluride (CdTe). In an embodiment of the present invention, the compound semiconductor may be doped. In an embodiment of the present invention, the compound semiconductor may be counter-doped.

In an embodiment of the present invention, the substrate 100 is partitioned vertically into stacked layers. In an embodiment of the present invention, the substrate 100 includes silicon-on-insulator (SOI). In an embodiment of the present invention, the SOI includes 0.2 um silicon over 1.0 um silicon oxide over 400.0-500.0 um silicon.

In an embodiment of the present invention, the substrate 100 includes bonded layers, such as bonded wafers. In an embodiment of the present invention, the substrate 100 includes SOI bonded to a silicon wafer.

In an embodiment of the present invention, the substrate 100 includes surface-mount technology (SMT).

In an embodiment of the present invention, the substrate 100 is partitioned laterally into contiguous blocks. In an embodiment of the present invention, the substrate 100 includes hybrid technology. In an embodiment of the present invention, the substrate 100 is included as part of a printed circuit board (PCB), a module, or a package.

As shown in an embodiment of the present invention in FIG. 1, the buffer layer 200 is formed over the substrate 100. In an embodiment of the present invention, the buffer layer 200 is located directly on a surface 110 of the substrate 100.

In an embodiment of the present invention, the buffer layer 200 includes a single layer. In an embodiment of the present invention, the buffer layer 200 includes a dual layer. In an embodiment of the present invention, the buffer layer 200 includes a multilayer.

In an embodiment of the present invention, the buffer layer 200 includes a single crystal structure.

In an embodiment of the present invention, the buffer layer 200 includes a flat and smooth surface 210 without any faceting. The surface morphology may be characterized with an Atomic Force Microscope (AFM).

In an embodiment of the present invention, the buffer layer 200 includes a protective barrier. In an embodiment of the present invention, the buffer layer 200 includes a capping layer.

In an embodiment of the present invention, the buffer layer 200 prevents interdiffusion at an interface 110 with the underlying substrate 100 by serving as a diffusion barrier for atoms or ions into or out of the substrate 100.

In an embodiment of the present invention, the buffer layer 200 prevents oxidation at the interface 110 with the underlying substrate 100 by blocking oxygen or water. In an embodiment of the present invention, the buffer layer 200 is resistant to oxidation up to at least 600 degrees Centigrade.

In an embodiment of the present invention, the buffer layer 200 prevents reaction at the interface 110 with the underlying substrate 100 by having a low chemical reactivity with the underlying substrate 100.

In an embodiment of the present invention, minimal interdiffusion or chemical reaction occurs at the interface 110 between the buffer layer 200 and the underlying substrate 100. In an embodiment of the present invention, the interface 110 between the buffer layer 200 and the underlying substrate 100 is thin, narrow, sharp, and abrupt. The interface morphology is observed with a Transmission Electron Microscope (TEM). The interface composition gradient is characterized with a secondary ion mass spectrometer (SIMS).

In an embodiment of the present invention, the buffer layer 200 is electrically insulating. In an embodiment of the present invention, the buffer layer 200 has a resistivity at room temperature (300 degrees Kelvin) of greater than (1.0E+3) ohm-cm.

In an embodiment of the present invention, the buffer layer has a thickness to provide electrical insulation over the substrate 100 without leakage or breakdown.

In an embodiment of the present invention, the buffer layer 200 is electrically conducting. In an embodiment of the present invention, the buffer layer 200 has a resistivity at room temperature (300 degrees Kelvin) of (5.0E−5)-(1.0E−4) ohm-cm. In an embodiment of the present invention, the buffer layer 200 has a resistivity at room temperature (300 degrees Kelvin) of (1.0E−4)-(5.0E−3) ohm-cm.

In an embodiment of the present invention, the buffer layer 200 has a coefficient of thermal expansion (CTE) that is well-matched with the CTE of the underlying substrate 100. The layers 100, 200 that form or surround the interface 110 will not crack or delaminate even when heated or cooled rapidly if the constituent materials have similar CTE.

In an embodiment of the present invention, the buffer layer 200 is formed from a material that is tough and is thus resistant to cracking or fracturing.

In an embodiment of the present invention, the buffer layer 200 is formed from a material with high density, low internal stress, good adhesion, and high resistance to cracking or fracturing.

In an embodiment of the present invention, the buffer layer 200 is thin enough to prevent cracking but thick enough to provide complete physical coverage over a surface 110 of the substrate 100 without any void or pinhole.

In an embodiment of the present invention, the buffer layer 200 has a thickness selected from a range of 5-20 nm. In an embodiment of the present invention, the buffer layer 200 has a thickness selected from a range of 20-40 nm. In an embodiment of the present invention, the buffer layer 200 has a thickness selected from a range of 40-65 nm.

In an embodiment of the present invention, the buffer layer 200 includes a growth template layer. In an embodiment of the present invention, the buffer layer 200 orients growth of an overlying layer. In an embodiment of the present invention, the buffer layer 200 enhances crystallization of the overlying layer. In an embodiment of the present invention, the buffer layer 200 reduces a crystallization temperature of the overlying layer. In an embodiment of the present invention, the buffer layer 200 helps development and growth of grains in a microstructure of the overlying layer. In an embodiment of the present invention, the buffer layer 200 improves surface roughness and morphology of the overlying layer. In an embodiment of the present invention, the buffer layer 200 influences and improves ferroelectric properties of the overlying layer.

In an embodiment of the present invention, the buffer layer 200 is a single crystal film. In an embodiment of the present invention, the buffer layer 200 is formed epitaxially over the underlying substrate 100. Epitaxy refers to a state or condition in which a deposited material 200 aligns to a crystallographic orientation of an underlying material 100.

In an embodiment of the present invention, the buffer layer 200 is formed epitaxially over the underlying substrate 100 even though the lattice constants of the buffer layer 200 and the underlying substrate 100 are mismatched by 0.0-1.5%. In an embodiment of the present invention, the buffer layer 200 is formed epitaxially over the underlying substrate 100 even though the lattice constants of the buffer layer 200 and the underlying substrate 100 are mismatched by 1.5-3.5. In an embodiment of the present invention, the buffer layer 200 is formed epitaxially over the underlying substrate 100 even though the lattice constants of the buffer layer 200 and the underlying substrate 100 are mismatched by 3.5-6.0%.

In an embodiment of the present invention, the buffer layer 200 is formed with a manufacture-friendly process. Certain processes, such as physical vapor deposition (PVD), sputtering, chemical vapor deposition (CVD), and e-beam deposition, are commonly used in semiconductor integrated circuits (IC) manufacturing and thus are manufacture-friendly processes.

In an embodiment of the present invention, the buffer layer 200 is formed by PVD. In an embodiment of the present invention, the buffer layer 200 is formed by sputtering. In an embodiment of the present invention, an electrically conducting buffer layer 200 is formed by direct current (DC) magnetron sputtering. In an embodiment of the present invention, an electrically insulating buffer layer 200 is formed by radio frequency (RF) magnetron sputtering. In an embodiment of the present invention, the buffer layer 200 is formed by ion beam sputtering. In an embodiment of the present invention, the buffer layer 200 is formed by low-pressure plasma-jet sputtering.

In an embodiment of the present invention, the buffer layer 200 is formed by CVD. In an embodiment of the present invention, the buffer layer 200 is formed by plasma-enhanced chemical vapor deposition (PECVD).

In an embodiment of the present invention, the buffer layer 200 is formed by metal-organic chemical vapor deposition (MOCVD). In an embodiment of the present invention, the ferroelectric layer 400 includes photo-assisted metal-organic chemical vapor deposition (PAMOCVD).

In comparison, other deposition processes, such as, molecular beam epitaxy (MBE) and pulsed laser deposition (PLD), are not widely used in semiconductor IC manufacturing and, thus, are not manufacture-friendly processes.

The buffer layer 200 may be formed under vacuum. The buffer layer 200 may be formed in a plasma. The buffer layer 200 may be formed by using an inert gas, such as argon, to bombard a target having a stoichiometric composition. Sputtering applies a bias field on the buffer layer 200 during deposition of material to increase thickness. In an embodiment of the present invention, the bias field may favor a polar domain pattern or configuration in the buffer layer 200.

In an embodiment of the present invention, the buffer layer 200 is formed by an electron-beam process. In an embodiment of the present invention, the buffer layer 200 is formed by electron-beam evaporation.

In an embodiment of the present invention, the buffer layer 200 is formed with a manufacture-friendly process at a low temperature. In an embodiment of the present invention, the buffer layer 200 is formed at a temperature selected from a range of 150-200 degrees Centigrade. In an embodiment of the present invention, the buffer layer 200 is formed at a temperature selected from a range of 200-275 degrees Centigrade.

In an embodiment of the present invention, the buffer layer 200 is formed with a manufacture-friendly process at a moderate temperature. In an embodiment of the present invention, the buffer layer 200 is formed at a temperature selected from a range of 275-375 degrees Centigrade. In an embodiment of the present invention, the buffer layer 200 is formed at a temperature selected from a range of 375-500 degrees Centigrade.

In an embodiment of the present invention, the buffer layer 200 is formed with a manufacture-friendly process at a high temperature. In an embodiment of the present invention, the buffer layer 200 is formed at a temperature selected from a range of 500-650 degrees Centigrade. In an embodiment of the present invention, the buffer layer 200 is formed at a temperature selected from a range of 650-825 degrees Centigrade.

In an embodiment of the present invention, the buffer layer 200 is formed with a manufacture-friendly process, such as PVD, sputtering, electron-beam evaporation, or CVD, with a deposition rate selected from a range of 3-6 nm/minute. In an embodiment of the present invention, the buffer layer 200 is formed with a manufacture-friendly process, such as sputtering or electron-beam evaporation, with a deposition rate selected from a range of 6-15 nm/min. In an embodiment of the present invention, the buffer layer 200 is formed with a manufacture-friendly process, such as sputtering or electron-beam evaporation, with a deposition rate selected from a range of 15-45 nm/min.

A smaller grain size and a lower film deposition rate may result in a smoother surface.

In an embodiment of the present invention, the buffer layer 200 is not annealed.

In an embodiment of the present invention, the buffer layer 200 is annealed in situ while deposition is in progress. In an embodiment of the present invention, the buffer layer 200 is annealed after deposition but without breaking vacuum. In an embodiment of the present invention, the buffer layer 200 is annealed ex situ after deposition is complete.

In an embodiment of the present invention, the buffer layer 200 is processed with a rapid thermal anneal (RTA). In an embodiment of the present invention, the buffer layer 200 is processed with a spike anneal. In an embodiment of the present invention, the buffer layer 200 is processed with a laser anneal.

In an embodiment of the present invention, the buffer layer 200 is annealed at a temperature selected from a range of 575-625 degrees Centigrade. In an embodiment of the present invention, the buffer layer 200 is annealed at a temperature selected from a range of 625-725 degrees Centigrade. In an embodiment of the present invention, the buffer layer 200 is annealed at a temperature selected from a range of 725-875 degrees Centigrade.

In an embodiment of the present invention, the buffer layer 200 is not annealed per se, but is subsequently exposed to a temperature that is significantly higher than the temperature originally used for depositing the buffer layer 200.

In an embodiment of the present invention, the buffer layer 200 is annealed in air. In an embodiment of the present invention, the buffer layer 200 is annealed in oxygen.

In an embodiment of the present invention, the substrate 100 is a silicon wafer with a (001) single crystal orientation. In an embodiment of the present invention, the buffer layer 200 is a binary oxide, such as magnesium oxide (MgO) which has a cubic halide lattice structure and (001) as a lowest energy surface. Single-crystal MgO has a lattice constant of 0.4213 nm which is about 7.5% larger than the corresponding 45-degree rotated silicon lattice dimension of 0.384 nm (silicon lattice constant divided by square root of 2 which is 0.543/1.414).

The MgO is an insulator with a large band gap and an index of refraction of 1.735. The index of refraction is measured by an ellipsometer. The MgO is highly ionic with a NaCl structure and will form over a tetrahedral semiconductor substrate that may be selected from a range of partially ionic to completely covalent. The MgO is neither ferroelectric nor superconducting.

In an embodiment of the present invention, the MgO is doped with an element having a smaller radius, such as beryllium, to improve the lattice matching of the buffer layer 200 to the underlying silicon in the substrate 100.

In an embodiment of the present invention, the substrate 100 is a silicon wafer with a (111) single crystal orientation. In an embodiment of the present invention, the buffer layer 200 is a rare-earth binary oxide with a cubic fluorite lattice structure and (111) as a lowest energy surface. In an embodiment of the present invention, the rare-earth binary oxide includes, but is not limited to, yttrium oxide (YO₂), zirconium oxide (ZrO₂), or erbium oxide (ErO₂). The lattice constant of the rare-earth binary oxide matches the lattice constant of the silicon in the substrate 100 fairly well.

In an embodiment of the present invention, the rare-earth binary oxide is doped with an element having a smaller radius to improve lattice matching to the silicon in the substrate 100.

Next, a bottom electrode 300 is formed epitaxially over the buffer layer 200.

In an embodiment of the present invention, the bottom electrode 300 is located directly on a surface 210 of the buffer layer 200.

In an embodiment of the present invention, minimal interdiffusion or chemical reaction occurs at the interface 210 between the bottom electrode 300 and the underlying buffer layer 200. In an embodiment of the present invention, the interface 210 between the bottom electrode 300 and the underlying buffer layer 200 is thin, narrow, sharp, and abrupt.

In an embodiment of the present invention, the bottom electrode 300 includes a single layer. In an embodiment of the present invention, the bottom electrode 300 includes a dual layer. In an embodiment of the present invention, the bottom electrode 300 includes a multilayer.

In an embodiment of the present invention, the bottom electrode 300 includes a single crystal structure.

In an embodiment of the present invention, the bottom electrode 300 includes a flat and smooth surface 310 without any faceting.

In an embodiment of the present invention, the bottom electrode 300 includes an electrically conductive material. In an embodiment of the present invention, the bottom electrode 300 includes a metal, such as gold (Au). In an embodiment of the present invention, the bottom electrode 300 includes, but is not limited to, SrRuO₃ (SRO) or LaNiO₃ (LNO). The LaNiO₃ is an n-type metallic conductor at room temperature that has a lattice constant which matches well with the lattice constant of many ferroelectric perovskite oxides.

In an embodiment of the present invention, the bottom electrode 300 has a thickness selected from a range of 5-20 nm. In an embodiment of the present invention, the bottom electrode 300 has a thickness selected from a range of 20-70 nm. In an embodiment of the present invention, the bottom electrode 300 has a thickness selected from a range of 70-210 nm.

In an embodiment of the present invention, the bottom electrode 300 is a single crystal film. In an embodiment of the present invention, the bottom electrode 300 is formed epitaxially over the buffer layer 200. Epitaxy refers to a state or condition in which a deposited material 300 aligns to a crystallographic orientation of an underlying material 200.

In an embodiment of the present invention, the bottom electrode 300 is formed epitaxially over the buffer layer 200 even though the lattice constants of the bottom electrode 300 and the buffer layer 200 are mismatched by 0.0-1.5%. In an embodiment of the present invention, the bottom electrode 300 is formed epitaxially over the buffer layer 200 even though the lattice constants of the bottom electrode 300 and the buffer layer 200 are mismatched by 1.5-3.5%. In an embodiment of the present invention, the bottom electrode 300 is formed epitaxially over the buffer layer 200 even though the lattice constants of the bottom electrode 300 and the buffer layer 200 are mismatched by 3.5-6.0%.

Then, an electronically active layer is formed over the bottom electrode 300. The electronically active layer may include a conductor, a semiconductor, a superconductor, or a ferroelectric material.

In an embodiment of the present invention, the electronically active layer that is formed over the bottom electrode 300 includes storage media, such as a ferroelectric layer 400. Ferroelectricity refers to a characteristic in which a permanent electric dipole moment is controlled by an external electric field. Epitaxy enhances a dipole moment by aligning the dipoles.

In an embodiment of the present invention, the ferroelectric layer 400 has a large remanent polarization (Pᵣ), a low coercive field, a low leakage current density, and a high fatigue resistance. In an embodiment of the present invention, a device formed with the ferroelectric layer 400 includes features, such as ease of writing, ease of erasing, scalability, and excellent signal-to-noise ratio (SNR).

In an embodiment of the present invention, the ferroelectric layer 400 includes a lead titanate, PbTiO₃ (PT).

In an embodiment of the present invention, the ferroelectric layer 400 includes a zirconium-modified lead titanate, PbZrₓTi₁₋ₓO₃ (PZT) simple solid solution.

The property of the PZT depends strongly on a compositional ratio of Zr/Ti that is selected. In an embodiment of the present invention, a tetragonal structure and a rhombohedral structure for the PZT coexist at a morphotropic phase boundary (MPB) when the Zr/Ti ratio approaches 52/48.

In an embodiment of the present invention, the PZT has a tetragonal structure when the Zr/Ti ratio is lower than 52/48 (Ti-rich). In an embodiment of the present invention, the Zr/Ti ratio is between 10/90 and 40/60. In an embodiment of the present invention, the Zr/Ti ratio is 20/80.

In an embodimen of the present invention, the PZT has a rhombohedral structure when the Zr/Ti ratio is higher than 52/48 (Zr-rich). In an embodiment of the present invention, the Zr/Ti ratio is between 60/40 and 80/20 which results in a higher switchable polarization and a more clearly defined switching voltage. In an embodiment of the present invention, the Zr/Ti ratio is 70/30.

In an embodiment of the present invention, the ferroelectric layer 400 includes a lanthanum-modified lead titanate, PbₓLa₁₋ₓTiO₃ (PLT) simple solid solution.

In an embodiment of the present invention, the ferroelectric layer 400 includes a Pb_{1-y}La_{y}Zr₁₋ₓTiₓO₃ (PLZT) coupled solid solution.

In an embodiment of the present invention, the ferroelectric layer 400 includes a SrBi₂Ta₂O₉ (SBT) layered perovskite.

In an embodiment of the present invention, the ferroelectric layer 400 includes a BaₓSr₁₋ₓTiO₃ (BST).

In an embodiment of the present invention, the ferroelectric layer 400 includes a bismuth ferrite, BiFeO₃ (BFO). The ferroelectric property of a multiferroic BFO thin film is modified considerably by a magnetic field. In an embodiment of the present invention, a ratio of 1.1 Bi: 1.0 Fe for the BFO resulted in the best crystallinity and the best ferroelectric property.

In an embodiment of the present invention, the ferroelectric layer 400 includes bismuth ferrite and lead titanate, BiFeO₃—PbTiO₃ (BFPT).

In an embodiment of the present invention, the ferroelectric layer 400 includes a polycrystalline structure. In an embodiment of the present invention, the ferroelectric layer 400 has a grain size selected from a range of 8-20 nm. In an embodiment of the present invention, the ferroelectric layer 400 has a grain size selected from a range of 20-40 nm. In an embodiment of the present invention, the ferroelectric layer 400 has a grain size selected from a range of 40-60 nm.

In an embodiment of the present invention, the ferroelectric layer 400 includes a crystalline structure. A high density may be achieved by forming the ferroelectric layer 400 as a single-crystal film. In an embodiment of the present invention, the single crystal film has lower leakage current than a polycrystalline film. In an embodiment of the present invention, the single crystal film has less optical scattering than a polycrystalline film.

In an embodiment of the present invention, the ferroelectric layer 400 is a single crystal film. In an embodiment of the present invention, the ferroelectric layer 400 is formed epitaxially over the bottom electrode 300. Epitaxy refers to a state or condition in which a deposited material 400 aligns to a crystallographic orientation of an underlying material 300.

In an embodiment of the present invention, the ferroelectric layer 400 is formed epitaxially over the bottom electrode 300 even though the lattice constants of the ferroelectric layer 400 and the bottom electrode 300 are mismatched by 0.0-1.5%. In an embodiment of the present invention, the ferroelectric layer 400 is formed epitaxially over the bottom electrode 300 even though the lattice constants of the ferroelectric layer 400 and the bottom electrode 300 are mismatched by 1.5-3.5%. In an embodiment of the present invention, the ferroelectric layer 400 is formed epitaxially over the bottom electrode 300 even though the lattice constants of the ferroelectric layer 400 and the bottom electrode 300 are mismatched by 3.5-6.0%.

In an embodiment of the present invention, the ferroelectric layer 400 has a thickness selected from a range of 4-20 nm. In an embodiment of the present invention, the ferroelectric layer 400 has a thickness selected from a range of 20-80 nm. In an embodiment of the present invention, the ferroelectric layer 400 has a thickness selected from a range of 80-240 nm.

In an embodiment of the present invention, the ferroelectric layer 400 includes a single layer. In an embodiment of the present invention, the ferroelectric layer 400 includes a dual layer. In an embodiment of the present invention, the ferroelectric layer 400 includes a multilayer. In an embodiment of the present invention, the ferroelectric layer 400 includes a superlattice.

In an embodiment of the present invention, the ferroelectric film layer 400 is formed at a temperature selected from a range of 60-180 degrees Centigrade. In an embodiment of the present invention, the ferroelectric film layer 400 is formed at a temperature selected from a range of 180-450 degrees Centigrade. In an embodiment of the present invention, the ferroelectric film layer 400 is formed at a temperature selected from a range of 450-900 degrees Centigrade.

In an embodiment of the present invention, the ferroelectric layer 400 is subsequently annealed in an inert environment, such as argon. In an embodiment of the present invention, the ferroelectric layer 400 is subsequently annealed in an oxidizing environment, such as oxygen.

In an embodiment of the present invention, the ferroelectric layer 400 is annealed at a temperature selected from a range of 400-550 degrees Centigrade. In an embodiment of the present invention, the ferroelectric layer 400 is annealed at a temperature selected from a range of 550-750 degrees Centigrade. In an embodiment of the present invention, the ferroelectric layer 400 is annealed at a temperature selected from a range of 750-1,000 degrees Centigrade.

Depending upon cation composition, oxygen content, and temperature, one or more crystallographic phases may be stable in the ferroelectric layer 400. In an embodiment of the present invention, the stable crystallographic phases may include orthorhombic, rhombohedral, or monoclinic symmetry.

The structural properties of a single-crystal thin film or layer is characterized by in situ reflection high-energy electron diffraction (RHEED) and x-ray diffraction (XRD). The chemical composition and thickness of the thin film is determined by wavelength dispersive spectroscopy (WDS). Thickness may also be determined by Rutherford backscattering spectroscopy (RBS) or a profilometer.

In an embodiment of the present invention, a probe-based storage system may include a movable x-y stage, a multiple conductive cantilever probe array, and a data signal processing module. The probe-based storage system is not limited by photolithography. Instead, the storage density depends on a bit size that is defined by probe technology and storage media material properties. The probe or the media will move physically so an initial latency is high.

The probe-based storage system may include a seek-and-scan probe (SSP). The SSP includes a microelectromechanical system (MEMS) with transducers, sensors, and actuators. The track pitch and position of the multiple probes in the array are determined by nano-positioning. The tip scaling is determined by tip field focusing. In an embodiment of the present invention, the probe tip has a radius of 20 nm. In an embodiment of the present invention, the probe tip has a radius of 12 nm. In an embodiment of the present invention, the probe tip has a radius of 7 nm.

A short voltage pulse is applied between a bottom electrode 300 and the probe tip while scanning a surface 410 of the storage media, such as the ferroelectric layer 400. The voltage pulse applied to the probe tip will initiate a local switching of domains in the storage media, such as the ferroelectric layer 400.

The voltage pulse can write a domain in the storage media, such as the ferroelectric layer 400 with a pattern of a one-dimensional feature, such as a dot, or a two-dimensional feature, such as a line. In an embodiment of the present invention, the polarization is in-plane. In an embodiment of the present invention, the polarization is out-of-plane.

A sign of the voltage pulse determines whether a polarization vector points from or to a plane of the ferroelectric layer 400. The polarization direction in the ferroelectric layer 400 may be sensed and read back by using a very low voltage.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

We claim:

1. A method comprising:
providing a substrate;
forming a buffer layer epitaxially over said substrate with a manufacture-friendly process;
forming a bottom electrode epitaxially over said buffer layer; and
forming a ferroelectric layer epitaxially over said bottom electrode.

2. The method of claim 1 wherein said manufacture-friendly process comprises radio frequency (RF) magnetron sputtering.

3. The method of claim 1 wherein said manufacture-friendly process comprises ion beam sputtering.

4. The method of claim 1 wherein said manufacture-friendly process comprises low-pressure plasma-jet sputtering.

5. The method of claim 1 wherein said manufacture-friendly process comprises electron-beam evaporation.

6. The method of claim 1 further comprising applying a bias field on said buffer layer while forming said buffer layer.

7. The method of claim 1 further comprising doping said buffer layer.

8. A structure comprising:
a substrate, said substrate comprising a silicon wafer with a (001) single crystal orientation;
a buffer layer disposed over said substrate, said buffer layer comprising a binary oxide having a cubic halide lattice structure with (001) as a lowest energy surface;
a bottom electrode disposed over said buffer layer; and
a ferroelectric layer disposed over said bottom electrodes.

9. The structure of claim 8 wherein said buffer layer comprises MgO.

10. The structure of claim 8 wherein said buffer layer is further doped with an element having a smaller radius to improve lattice matching.

11. The structure of claim 10 wherein said element comprises Beryllium.

12. A structure comprising:
a substrate, said substrate comprising a silicon wafer with a (111) single crystal orientation;
a buffer layer disposed over said substrate, said buffer layer comprising a rare-earth binary oxide having a cubic fluorite lattice structure symmetry with (111) as a lowest energy surface;
a bottom electrode disposed over said buffer layer; and
a ferroelectric layer disposed over said bottom electrodes.

13. The structure of claim 12 wherein said buffer layer comprises ZrO₂.

14. The structure of claim 12 wherein said buffer layer comprises YO₂.

15. The structure of claim 12 wherein said buffer layer comprises ErO₂.

16. The structure of claim 12 wherein said buffer layer is further doped with an element having a smaller radius to improve lattice matching.
